(19) United States
(12) Patent Application Publication
(10) Pub. No.: US 2016/0316579 A1
(43) Pub. Date: Oct. 27, 2016

(54) MOUNTING HANDLES FOR ELECTRICAL ENCLOSURES

(71) Applicants: Kyle Steven Barna, Syracuse, NY (US); Gregory Davis, Pittsford, NY (US)

(72) Inventors: Kyle Steven Barna, Syracuse, NY (US); Gregory Davis, Pittsford, NY (US)

(21) Appl. No.: 14/694,443

(22) Filed: Apr. 23, 2015

(51) Int. Cl. H05K 5/02; F16L 3/12

(52) U.S. Cl. CPC H05K 5/023; F16L 3/12

(57) ABSTRACT

A handle for mounting an electrical enclosure to a mounting structure is described herein. The handle can include a base having at least one enclosure coupling feature, where the at least one enclosure coupling feature is configured to couple to the electrical enclosure. The handle can also include a body disposed adjacent to the base. The handle can further include a structure coupling feature that protrudes from the body, where the structure coupling feature is configured to removably couple to the mounting structure. The mounting structure can have an opening in which the structure coupling feature is disposed.

### TECHNICAL FIELD

The present disclosure relates generally to electrical cable connectors and other enclosures, and more particularly to systems, methods, and devices for mounting electrical cable connectors and other enclosures to structures such as a strut.

### BACKGROUND

Electrical enclosures (such as electrical connectors) are used in a number of applications (e.g., photovoltaic (PV) solar) and have a number of different sizes and configurations. Sometimes, such electrical enclosures are moved by a user to perform maintenance, to replace equipment, to change the location of equipment, and/or to perform some other function that involves the electrical enclosure. In such a case, the electrical enclosure can be moved to a temporary location by a user.

### SUMMARY

In general, in one aspect, the disclosure relates to a handle for mounting an electrical enclosure to a mounting structure. The handle can include a base having at least one enclosure coupling feature, where the at least one enclosure coupling feature is configured to couple to the electrical enclosure. The handle can also include a body disposed adjacent to the base. The handle can further include a structure coupling feature that protrudes from the body, where the structure coupling feature is configured to removably couple to the mounting structure. The mounting structure can include an opening in which the structure coupling feature is disposed.

In another aspect, the disclosure can generally relate to an electrical enclosure. The electrical enclosure can include a housing and a handle coupled to and disposed on an exterior surface of the housing. The handle of the electrical enclosure can include a base having at least one enclosure coupling feature, where the at least one enclosure coupling feature is configured to couple to the housing. The handle of the electrical enclosure can also include a body disposed adjacent to the base. The handle of the electrical enclosure can further include a structure coupling feature that protrudes from the body, where the structure coupling feature is configured to removably couple to the mounting structure. The mounting structure can include an opening in which the structure coupling feature is disposed.

In yet another aspect, the disclosure can generally relate to an electrical enclosure system. The electrical enclosure system can include a mounting structure having an opening. The electrical enclosure system can also include an electrical enclosure. The electrical enclosure system can further include a handle coupled to and disposed on an exterior surface of the electrical enclosure. The handle of the electrical enclosure can include a base having at least one enclosure structure coupling feature, where the at least one enclosure structure coupling feature is coupled to the electrical enclosure. The handle of the electrical enclosure can also include a body disposed adjacent to the base. The handle of the electrical enclosure can further include a coupling feature that protrudes from the body, where the structure coupling feature is removably disposed in the opening and coupled to the mounting structure.

These and other aspects, objects, features, and embodiments will be apparent from the following description and the appended claims.

### BRIEF DESCRIPTION OF THE DRAWINGS

The drawings illustrate only example embodiments and are therefore not to be considered limiting in scope, as the example embodiments may admit to other equally effective embodiments. The elements and features shown in the drawings are not necessarily to scale, emphasis instead being placed upon clearly illustrating the principles of the example embodiments. Additionally, certain dimensions or positionings may be exaggerated to help visually convey such principles. In the drawings, reference numerals designate like or corresponding, but not necessarily identical, elements.

FIGS. 1A and 1B show a mounting handle for an electrical enclosure in accordance with certain example embodiments.

FIGS. 2A and 2B show an electrical enclosure with the mounting handle of FIGS. 1A and 1B in accordance with certain example embodiments.

FIGS. 3A and 3B show an example of a mounting structure to which example embodiments can be coupled.

FIGS. 4A and 4B show another mounting handle for an electrical enclosure in accordance with certain example embodiments.

FIGS. 5A-5C show a mounting handle beginning to couple to a mounting structure in accordance with certain example embodiments.

FIGS. 6A and 6B show the mounting handle of FIGS. 5A-5C in the process of coupling to a mounting structure in accordance with certain example embodiments.

FIGS. 7A-7C show the mounting handle of FIGS. 5A-5C coupled to a mounting structure in accordance with certain example embodiments.

### DETAILED DESCRIPTION

In general, example embodiments provide systems, methods, and devices for mounting handles for electrical enclosures. Example mounting handles for electrical enclosures provide a number of benefits. Such benefits can include, but are not limited to, operation by a user without tools (e.g., only by hand), portability of the electrical enclosures by a user, and securely mounting an electrical enclosure to a mounting structure on a temporary basis.

The example embodiments discussed herein can be directed to any type of application (e.g., a PV solar system, generation control systems, branch circuit management and protection). A user may be any person that interacts with example mounting handles for electrical enclosures. Examples of a user may include, but are not limited to, an engineer, an electrician, an instrumentation and controls technician, a mechanic, an operator, a consultant, a contractor, and a manufacturer's representative.

The mounting handles for electrical enclosures (or components thereof) described herein can be made of one or more of a number of suitable materials to allow the electrical enclosures to meet certain standards and/or regulations while also maintaining durability in light of the one or more conditions under which the electrical enclosures, including the example mounting handles, can be exposed. Examples of such materials can include, but are not limited to, aluminum, stainless steel, fiberglass, glass, plastic, ceramic, and rubber.

Example mounting handles for electrical enclosures, or portions thereof, described herein can be made from a single piece (as from a mold, injection mold, die cast, or extrusion process). In addition, or in the alternative, example mounting handles for electrical enclosures can be made from multiple pieces that are mechanically coupled to each other. In such a case, the multiple pieces can be mechanically coupled to each other using one or more of a number of coupling methods, including but not limited to epoxy, welding, fastening devices, compression fittings, mating threads, and slotted fittings. One or more pieces that are mechanically coupled to each other can be coupled to each other in one or more of a number of ways, including but not limited to fixedly, hingedly, removeably, slidably, and threadably.

Components and/or features described herein can include elements that are described as coupling, mounting, fastening, securing, or other similar terms. Such terms are merely meant to distinguish various elements and/or features within a component or device and are not meant to limit the capability or function of that particular element and/or feature. For example, a feature described as a “coupling feature” can couple, mount, secure, fasten, and/or perform other functions aside from merely coupling.

A coupling feature (including a complementary coupling feature) as described herein can allow one or more components and/or portions of an example handle (e.g., a base) to become mechanically coupled, directly or indirectly, to another portion (e.g., electrical enclosure, mounting structure) of an electrical enclosure system. A coupling feature can include, but is not limited to, a portion of a hinge, an aperture, a recessed area, a protrusion, a clamp, a slot, a spring clip, a tab, a detent, and mating threads. One portion of an example handle can be coupled to a component of an electrical enclosure system by the direct use of one or more coupling features.

In addition, or in the alternative, a portion of an example handle can be coupled to a component of an electrical enclosure system using one or more independent devices that interact with one or more coupling features disposed on an example handle and/or a component of an electrical enclosure system. Examples of such devices can include, but are not limited to, a pin, a hinge, a fastening device (e.g., a bolt, a screw, a rivet), and a spring. One coupling feature described herein can be the same as, or different than, one or more other coupling features described herein. A complementary coupling feature as described herein can be a coupling feature that mechanically couples, directly or indirectly, with another coupling feature.

Further, if a component of a figure is described but not expressly shown or labeled in that figure, the label used for a corresponding component in another figure can be inferred to that component. Conversely, if a component in a figure is labeled but not described, the description for such component can be substantially the same as the description for the corresponding component in another figure. The numbering scheme for the various components in the figures herein is such that each component is a three digit number and corresponding components in other figures have the identical last two digits.

In the foregoing figures showing example embodiments of mounting handles for electrical enclosures, one or more of the components shown may be omitted, repeated, and/or substituted. Accordingly, example embodiments of mounting handles for electrical enclosures should not be considered limited to the specific arrangements of components shown in any of the figures. For example, features shown in one or more figures or described with respect to one embodiment can be applied to another embodiment associated with a different figure or description.

As defined herein, an electrical enclosure is any type of cabinet or housing inside of which is disposed electrical and/or electronic equipment. Such electrical and/or electronic equipment can include, but is not limited to, electrical cables and/or electrical conductors. Examples of an electrical enclosure can include, but are not limited to, an electrical connector, a junction box, a motor control center, a breaker box, an electrical housing, a conduit, a control panel, an indicating panel, and a control cabinet.

In certain example embodiments, electrical enclosures to which example mounting handles are coupled are subject to meeting certain standards and/or requirements. For example, the National Electric Code (NEC), the National Electrical Manufacturers Association (NEMA), and the Institute of Electrical and Electronics Engineers (IEEE) set standards as to electrical enclosures, wiring, and electrical connections. Use of example embodiments described herein meet (and/or allow a corresponding device to meet) such standards when required. In some (e.g., PV solar) applications, additional standards particular to that application may be met by the electrical enclosures to which example mounting handles are coupled.

Example embodiments of mounting handles for electrical enclosures will be described more fully hereinafter with reference to the accompanying drawings, in which example embodiments of mounting handles for electrical enclosures are shown. Mounting handles for electrical enclosures may, however, be embodied in many different forms and should not be construed as limited to the example embodiments set forth herein. Rather, these example embodiments are provided so that this disclosure will be thorough and complete, and will fully convey the scope of mounting handles for electrical enclosures to those of ordinary skill in the art. Like, but not necessarily the same, elements (also sometimes called components) in the various figures are denoted by like reference numerals for consistency.

Terms such as “first”, “second”, “top”, “bottom”, “side”, “back”, “width”, “length”, “thickness”, “inner”, “outer”, “distal”, “upper”, “lower”, “left”, and “right” are used merely to distinguish one component (or part of a component or state of a component) from another. Such terms are not meant to denote a preference or a particular orientation, and are not meant to limit embodiments of mounting handles for electrical enclosures. In the following detailed description of the example embodiments, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

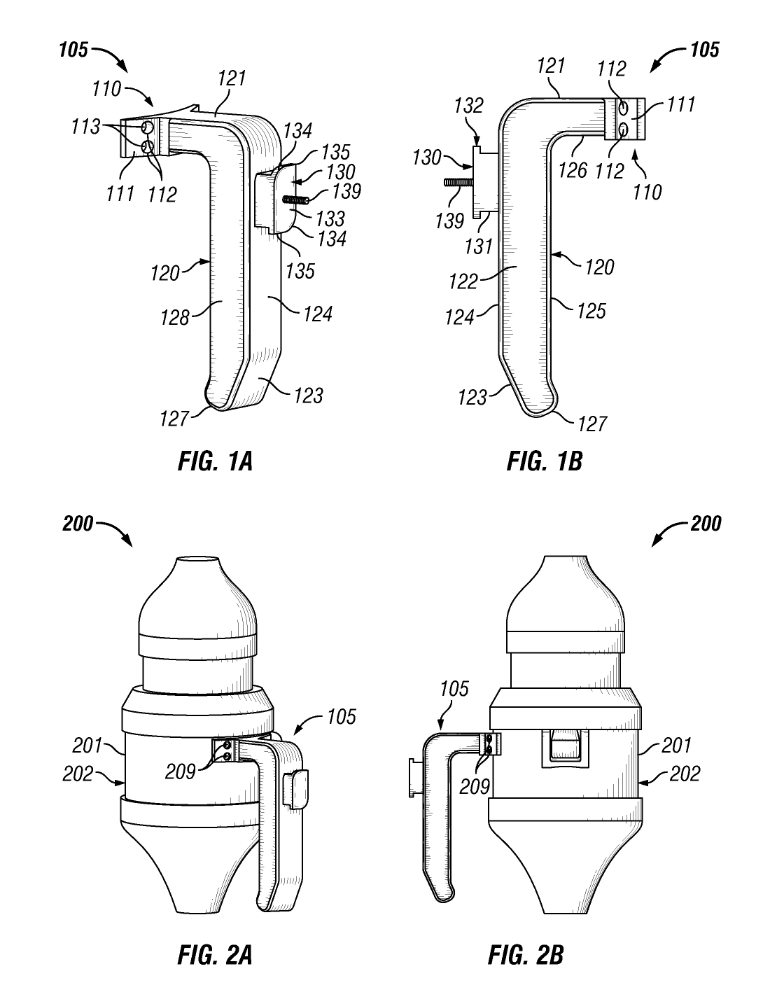

FIGS. 1A and 1B show a handle 105 (also called a mounting handle 105) for an electrical enclosure in accordance with certain example embodiments. In certain example embodiments, the handle 105 of FIGS. 1A and 1B include a base 110, a body 120, and at least one coupling feature 130 that protrudes from the body 120. The base 110 can include at least one coupling feature (also called an enclosure coupling feature) that allows the handle 105 to couple to an electrical enclosure. For example, as shown in FIGS. 1A and 1B, the handle 105 can have a number (in this case, four) apertures 113 that traverse an extension 111 of the base 110. In such a case, the apertures 113 are defined by a wall 112 in the extension 111.

In this example, there are two extensions 111 that extend from either side of the top of the body 120 of the handle 105, where the extensions 111 are symmetrical to each other. In alternative embodiments, the base 110 can have no extensions, one extension 111, or more than two extensions 111. If there are multiple extensions 111, one extension 111 can be configured the same as, or differently than, one or more of the other extensions 111. Further, an extension 111 can extend in any direction from or relative to the top of the body 120 of the handle 105. Any component (e.g., an extension 111) of the base 110 can have one or more features (e.g., a curvature along a surface that abuts against an electrical enclosure) to help facilitate the coupling between the handle 105 and the electrical enclosure to which the handle 105 is coupled.

In certain example embodiments, the body 120 of the handle 105 is adjacent to the base 110. The body 120 can have one or more portions, where each portion has one or more of a number of shapes and/or features. For example, as shown in FIGS. 1A and 1B, the body 120 can have a top portion, a main portion, and a bottom portion. When viewed cross-sectionally, each portion (e.g., top portion, main portion, bottom portion) of the body 120 can have any of a number of shapes and/or sizes. Examples of such shapes can include, but are not limited to, a square, a rectangle, a circle, an oval, a hexagon, and a triangle.

The top portion of the body 120 can be coupled to the base 110 and have a top surface 121, a left side surface 128, a right side surface 126, and a bottom surface 126. The main portion of the body 120 can be adjacent to the top portion and have a front surface 125, a back surface 124, the left side surface 128, and the right side surface 126. The bottom portion of the body 120 can be adjacent to the main portion and have a back surface 123, a bottom surface 127, the left side surface 128, and the right side surface 126.

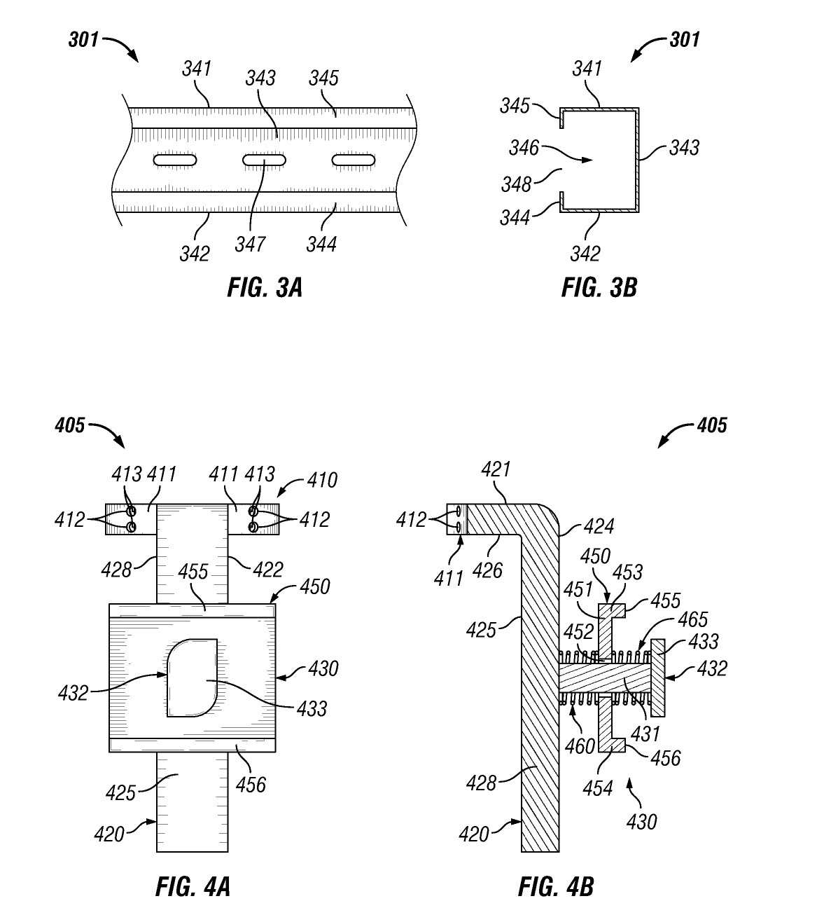

In certain example embodiments, the coupling feature 130 protrudes from the body 120. For example, in this case, the coupling feature 130 protrudes from the back surface 124 of the body 120. The coupling feature 130 (also called a structure coupling feature 130) can have one or more of a number of features that allow the coupling feature 130 to removeably couple the handle 105 to a mounting structure. An example of a mounting structure is shown below with respect to FIGS. 3A and 3B.

The components and/or configuration of a coupling feature 130 of the handle 105 can vary. For example, as shown in FIGS. 1A and 1B, the coupling feature 130 can include a stem 131 and an interior attachment feature 132. The stem 131 can be coupled (e.g., fixedly, removeably) to the body 120 and can have a length (measured from the side closest to the bottom portion of the handle 120 to the side closest to the top portion of the handle 120), a width (measured from the side closest to the left side surface 128 of the handle 120 to the side closest to the right side surface 126 of the handle 120), and a thickness (or height, measured as the distance that the stem 131 extends away from the handle 120). When viewed cross-sectionally, the stem 131 can have any of a number of shapes and/or sizes. Examples of such shapes can include, but are not limited to, a square, a rectangle, a circle, an oval, a hexagon, and a triangle.

The interior attachment feature 132 can be disposed (e.g., fixedly, removeably) at a distal end of the stem 131. The interior attachment feature 132 can have a body 133 that has a length and width that is greater than the length and width of the stem, while the thickness of the interior attachment feature 132 can be less than the thickness of the stem 131. In this way, as shown in FIGS. 1A and 1B, when the body 133 of the interior attachment feature 132 is substantially centered relative to the distal end of the stem 131, the body 133 of the interior attachment feature 132 extends laterally away from the stem 131 in all directions.

In certain example embodiments, when viewed from the front, the body 133 of the interior attachment feature 132 can be substantially rectangular or otherwise oblong, where one side is longer than an adjacent side. For example, the length of the body 133 of the interior attachment feature 132 can be greater than the width of the body 133 of the interior attachment feature 132. Alternatively, the width of the body 133 of the interior attachment feature 132 can be greater than the length of the body 133 of the interior attachment feature 132.

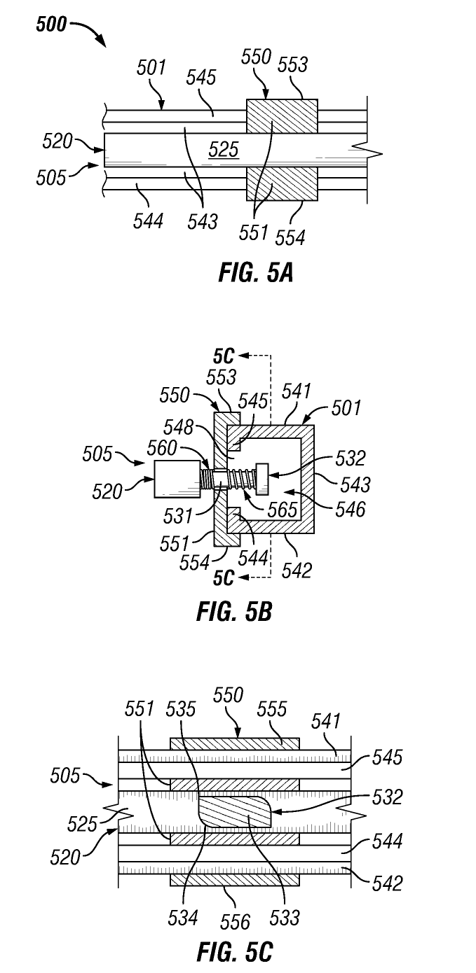

In certain example embodiments, the interior attachment feature 132 can include one or more features to assist a user in coupling the handle 105 to a mounting structure. For example, as shown in FIGS. 1A and 1B, at least one corner of the interior attachment feature 132 can have a rounded edge 134 that is adjacent to a corner with a squared edge 135. In this way, when there are four corners to the interior attachment feature 132, one pair of diagonally opposite corners are rounded, and the other pair of diagonally opposite corners are squared. As shown below with respect to FIGS. 5A-7C, this configuration of the interior attachment feature 132 can help a user manipulate the handle 105 relative to certain types of mounting structures. In certain example embodiments, any such configuration (e.g., rounded corners) of the body 133 of the interior attachment feature 132 can be mirrored, to scale, along the thickness of the stem 131.

Optionally, in certain example embodiments, the coupling feature 130 can include one or more pins 139 that each extends distally from the body 133 of the interior attachment feature 132. In such a case, the pin 139 can have characteristics (e.g., shape, width, length) that allow the pin 139 to couple to (e.g., be disposed within) a corresponding and complementary feature (e.g., an aperture) of the mounting structure. The pin 139 can be rigid or moveable (e.g., retractable) relative to the body 133 of the interior attachment feature 132. In some embodiments, a resilient device (e.g., a spring) can be disposed around, or integrated with, the pin 139 to allow the pin 139 to return to a normal position and/or to help maintain the pin 139 in a certain position with respect to a feature (e.g., an aperture) of a mounting structure.

The stem 131 and the interior attachment feature 132 of the coupling feature 130 can be oriented with respect to each other in any of a number of ways. For example, as shown in FIGS. 1A and 1B, when taken from a top view, the center line that runs through the thickness of the stem 131 is aligned with the center line that runs through the thickness of the interior attachment feature 132, and the length of the stem 131 is aligned with the length of the interior attachment feature 132. Further, the coupling feature 130 can be oriented with respect to the handle 120 in any of a number of ways. For example, as shown in FIGS. 1A and 1B, the coupling feature 130 can be centered relative to the width of the handle 120, but disposed closer to the top portion of the handle 120 relative to the bottom portion of the handle 120. Further, the length of the coupling feature 130 can be aligned with the length of the main portion of the handle 120.

FIGS. 2A and 2B show an electrical enclosure system 200 that includes an electrical enclosure 202 with the handle 105 of FIGS. 1A and 1B in accordance with certain example embodiments. Referring to FIGS. 1A-2B, the electrical enclosure 202 in this case is an electrical connector, and the handle 105 is coupled to a wall 201 of the electrical enclosure 202 using rivets 209 that traverse the apertures 113 in the base 110 of the handle 105 and at least a portion of the wall 201 of the electrical enclosure 202. In this way, when a user grips the handle 105, the user can manipulate the electrical enclosure 202.

FIGS. 3A and 3B show an example of a mounting structure 301 to which example embodiments can be coupled. In this case, the mounting structure 301 is a strut (also called, among other names, a bracket). The mounting structure 301 can have any of a number of features, including an opening in which the coupling feature of a handle can be disposed. For example, in this case, the mounting structure 301 has a C-shaped profile (as shown in FIG. 3B) that is formed by a top wall 341, a back wall 343, a bottom wall 342, an upper lip 345, and a lower lip 344. Between the upper lip 345 and the lower lip 344 is an opening 348 that leads to a cavity 346 of the C-shaped profile.

In some cases, disposed in or traversing the back wall 343 can be one or more of a number of apertures 347. These apertures 347 can act as complementary coupling features for one or more components (e.g., a pin 139) of the coupling feature of an example handle. The shape, size, and depth of the apertures 347 can be suitable to couple to the complementary coupling feature of the handle.

With a mounting structure 301 configured as shown in FIGS. 3A and 3B, the handle 105 of FIGS. 1A and 1B can be removably coupled to the mounting structure 301 by a user. For In this case, the height of the opening 348 between the upper lip 345 and the lower lip 344 can be greater than the width (measured from the edge of the body 133 closest to the left side surface 128 of the handle 120 to the edge of the body 133 closest to the right side surface 126 of the handle 120) of the body 133 of the interior attachment feature 132 but less than the height (measured from the edge of the body 133 closest to the top surface 121 of the handle 120 to the edge of the body 133 closest to the back surface 123 of the handle 120) of the body 133 of the interior attachment feature 132.

In such a case, when the handle 105 is positioned so that the length of the body 120 is substantially parallel to the opening 348 of the mounting structure 301, and when the interior attachment feature 132 is aligned with the opening 348 of the mounting structure 301, a user can move the handle 105 toward the mounting structure 301 until the body 120 of the handle 105 abuts against the upper lip 345 and the lower lip 344 of the mounting structure 301. When one pair of diagonally opposite corners of the body 133 of the interior attachment feature 132 is rounded, the length of the body 120 of the handle 105 can be positioned at some angle (e.g., 45°) that is antiparallel to the opening 348 of the mounting structure 301 and still be moved toward the mounting structure 301 until the body 120 of the handle 105 abuts against the upper lip 345 and the lower lip 344 of the mounting structure 301.

In this way, when the handle 105 is within a certain range of positions relative to the mounting structure 301, then a user can move the handle 105 toward the mounting structure 301 until the body 120 of the handle 105 abuts against the upper lip 345 and the lower lip 344 of the mounting structure 301. Similarly, when the handle 105 is within this range of positions relative to the mounting structure 301, then a user can move the handle 105 away from the mounting structure 301 so that the interior attachment feature 132 is removed from the cavity 346 and the opening 348 of the mounting structure 301.

When the body 120 of the handle 105 abuts against the upper lip 345 and the lower lip 344 of the mounting structure 301, then the interior attachment feature 132 is positioned inside the cavity 346 of the mounting structure 301. At this point, if the handle 105 is rotated (e.g., clockwise, counterclockwise) by some amount (e.g., until the body 120 of the handle 105 is substantially perpendicular to the opening 348 of the mounting structure 301), then the height of the body 133 of the interior attachment feature 132 prevents the handle 105 from being pulled away from the mounting structure 301. Specifically, when the handle 105 is rotated into a certain range of positions relative to the mounting structure 301, the top and/or the bottom (along its length) of the body 133 of the interior attachment feature 132 abuts against the upper lip 345 and/or the lower lip 344 of the mounting structure 301.

When this occurs, the handle 105 and the mounting structure 301 remain coupled to each other until the handle 105 is rotated back to within the range of positions relative to the mounting structure 301 so that the upper lip 345 and the lower lip 344 of the mounting structure 301 no longer interfere with the body 133 of the interior attachment feature 132. At that point, a user can move the handle 105 away from the mounting structure 301 so that the interior attachment feature 132 is removed from the cavity 346 and the opening 348 of the mounting structure 301.

For this interaction between the mounting structure 301 and the handle 105 to occur, the height of the stem 131 can be no greater than the distance of the opening 348 between the upper lip 345 and the lower lip 344 of the mounting structure 301. Also, the thickness of the stem 131 is at least as great as the thickness of the upper lip 345 and the lower lip 344 of the mounting structure 301. In addition, the height of the body 133 of the interior attachment feature 132 can be no greater than the distance between the top wall 341 and the bottom wall 342 of the mounting structure 301.

FIGS. 4A and 4B show another handle 405 (also called a mounting handle 405) for an electrical enclosure in accordance with certain example embodiments. The handle 405 of FIGS. 4A and 4B is substantially similar to the handle 105 of FIGS. 1A and 1B, except as described below. For example, the body 420 of the handle 405 lacks the bottom portion of the body 120 of the handle 105 of FIGS. 1A and 1B, but is otherwise substantially the same as the body 120 of the handle 105.

Referring to FIGS. 1A-4B, the interior attachment feature 432 of the coupling feature 430 of the handle 405 of FIGS. 4A and 4B is substantially the same as the interior attachment feature 132 of the coupling feature 130 of the handle 105 of FIGS. 1A and 1B. The stem 431 of the coupling feature 430 of the handle 405 of FIGS. 4A and 4B can be longer than the stem 131 of the coupling feature 130 of the handle 105 of FIGS. 1A and 1B. As a result, the interior attachment feature 432 can be separated further from the body 420 of the handle 405 relative to the distance between the interior attachment feature 132 and the body 120 of the handle 105. When viewed cross-sectionally along its length, the shape of the stem 431 can be circular.

Further, the coupling feature 430 of the handle 405 of FIGS. 4A and 4B have a number of additional features relative to the coupling feature 130 of the handle 105 of FIGS. 1A and 1B. For example, the coupling feature 430 of FIGS. 4A and 4B can include a bracket 450 and at least one resilient device (in this case, resilient device 460 and optional resilient device 465). In certain example embodiments, the bracket 450 is a component that is movably disposed around the stem 431 between the body 420 of the handle 405 and the interior attachment feature 432. For example, when the cross-sectional shape of the stem 431 when viewed along the length of the stem 431 is circular, the bracket 450 can rotate with respect to the stem 431 and/or slide along the stem 431 between the body 420 of the handle 405 and the interior attachment feature 432.

The bracket 450 can have a body 451 having an aperture 452 that traverses therethrough, an extension 453 that protrudes laterally away from one end (e.g., a top end) of the body 451, and another extension 454 that protrudes laterally away from an opposite end (e.g., a bottom end) of the body 451. The extension 453 and the extension 454 can extend toward the interior attachment feature 432. The extension 453 can have a distal end 455, and the extension 454 can have a distal end 456. The distance between the extension 453 and the extension 454 can be at least as great as the height of a portion of a mounting structure. For example, when the mounting structure 301 of FIGS. 3A and 3B is used, the distance between the extension 453 and the extension 454 can be at least as great as the height of the back wall 343.

The extension 453 and the extension 454 can extend at any of a number of angles from the body 451 of the bracket 450. For example, as shown in FIGS. 4A and 4B, each of the extension 453 and the extension 454 extend from the body 451 at substantially 90° (perpendicular). When viewed from the front, the body 451 of the bracket 450 can be substantially rectangular in shape, although the body 451 can have other shapes in alternative embodiments. In some cases, various components (e.g., the bracket 450, the interior attachment feature 432) can be made of and/or coated with a material (e.g., rubber) that promotes or facilitates that component to more easily couple to a portion of a mounting structure.

In certain example embodiments, the resilient device 460 (e.g., spring) is disposed around the stem 431 between the bracket 450 and the body 420 of the handle 405. The resilient device 460 has a force (generally called a spring force) that pushes the bracket 450 away from the body 420 of the handle 405 when the resilient device 460 is compressed. Similarly, optional resilient device 465 is disposed around the stem 431 between the bracket 450 and the body 433 of the interior attachment feature 432. The resilient device 465 has a force (generally called a spring force) that pushes the bracket 450 away from the body 433 of the interior attachment feature 432 when the resilient device 465 is compressed. Under this configuration, the resilient device 460 and the resilient device 465 oppose each other. The spring force of the resilient device 460 can be the same as, or different than, the spring force of the resilient device 465. For example, the spring force of the resilient device 460 can be greater than the spring force of the resilient device 465.

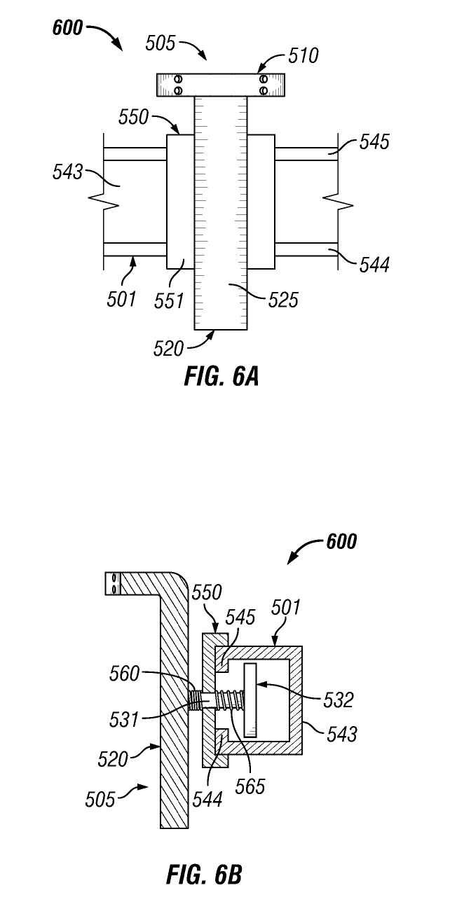

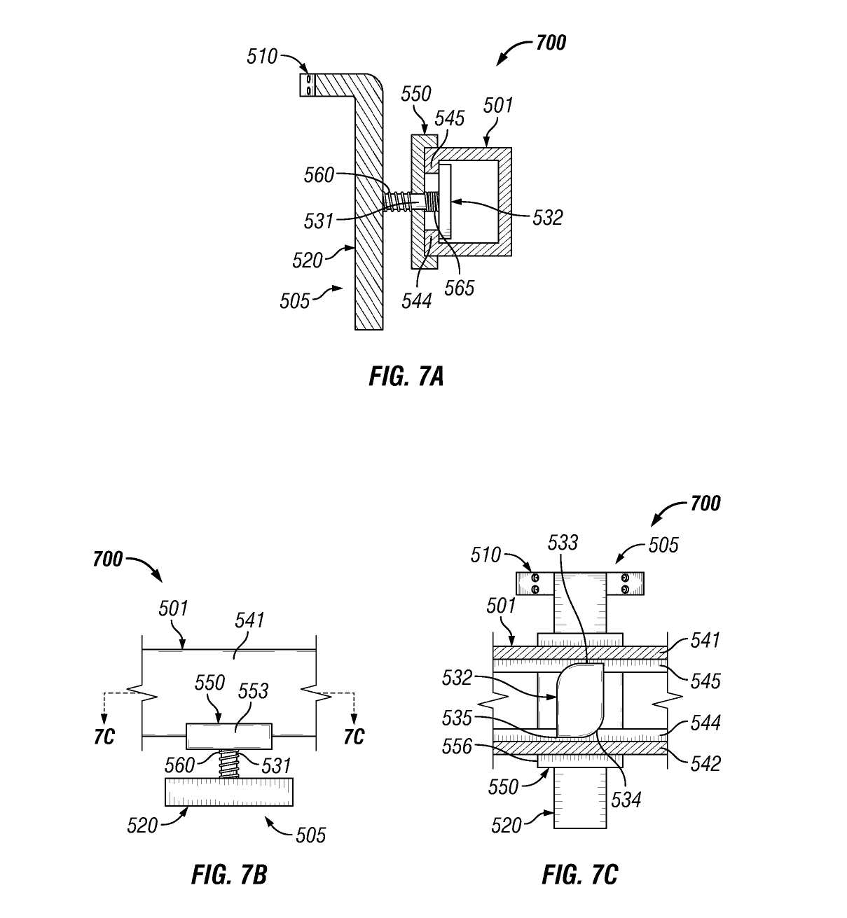

FIGS. 5A-7C show a mounting handle 505 interacting with a mounting structure 501 in accordance with certain example embodiments. Specifically, FIGS. 5A-5C show the mounting handle 505 beginning to couple to the mounting structure 501 in accordance with certain example embodiments. FIGS. 6A and 6B show the mounting handle 505 of FIGS. 5A-5C in the process of coupling to the mounting structure 501 in accordance with certain example embodiments. FIGS. 7A-7C show the mounting handle 505 of FIGS. 5A-5C coupled to the mounting structure 501 in accordance with certain example embodiments. The mounting handle 505 of FIGS. 5A-7C is substantially similar to the mounting handle 405 of FIGS. 4A and 4B. The mounting structure 501 of FIGS. 5A-7C is substantially similar to the mounting structure 301 of FIGS. 3A and 3B. The electrical enclosure is not shown coupled to the base 510 of the mounting handle 505 to more easily show how the mounting handle 505 couples to the mounting structure 501.

Referring to FIGS. 1A-7C, the electrical enclosure system 500 of FIGS. 5A-5C shows the mounting handle 505 beginning to couple to the mounting structure 501. FIG. 5A shows a front view of the electrical enclosure system 500. FIG. 5B shows a cross-sectional side view of the electrical enclosure system 500. FIG. 5C shows a cross-sectional back view of the electrical enclosure system 500. In the electrical enclosure system 500 of FIGS. 5A-5C, the mounting handle 505 is oriented such that the length of the body 520 and the length of the interior attachment feature 532 are aligned with the opening 548 in the mounting structure 501.

Further, the bracket 550 is oriented such that the extension 553 overlaps (e.g., abuts against) the top wall 541 of the mounting structure 501 and the extension 554 overlaps the bottom wall 542 of the mounting structure 501. In addition, the body 551 of the bracket 550 abuts against the upper lip 545 and the lower lip 544 of the mounting structure 501, which also causes the body 551 to be positioned adjacent to the opening 548. A user may rotate the bracket 500 relative to the stem 531 to achieve this orientation.

Once the interior attachment feature 532 passes the opening 548 and enters the cavity 546 of the mounting structure 501, the user can continue to apply a force that forces the interior attachment feature 532 further into the cavity 546. As shown in FIG. 5B, as this force continues to be applies, the resilient device 560 compresses, taking the resilient device 560 out of its normal position. When under compression, the resilient device 560 applies its spring force to separate the bracket 550 from the body 520 of the mounting handle 505. Thus, when the bracket 550 is engaged with the mounting structure 501, as shown in FIGS. 5A-5C, the resilient device 560 keeps the bracket 550 engaged with the mounting structure 501.

With the electrical enclosure system 600 of FIGS. 6A and 6B, the electrical enclosure system 500 of FIGS. 5A-5C is modified by rotating (changing the orientation of) the mounting handle 505. FIG. 6A shows a front view of the electrical enclosure system 600. FIG. 6B shows a cross-sectional side view of the electrical enclosure system 600. In this case, the mounting handle 505 has been rotated 90° counter-clockwise in FIGS. 6A and 6B compared to the orientation of the mounting handle 505 with respect to the mounting structure 501 in FIGS. 5A-5C.

Since the bracket 550 is secured against the mounting structure 501, the mounting handle 505 can freely rotate with respect to the stem 531 and otherwise remain stationary with respect to the mounting bracket 501. When the mounting handle 505 is rotated, the inward force (toward the back wall 543 of the mounting structure in this example) applied by the user against the mounting handle 505 can be maintained so that the interior attachment feature 532 does not contact the upper lip 545 or the lower lip 544 of the mounting structure 501. In such a case, the mounting handle 505 can more freely rotate with respect to the stem 531.

With the electrical enclosure system 700 of FIGS. 7A-7C, the electrical enclosure system 600 of FIGS. 6A and 6B is modified by removing the inward force to the mounting handle 505 by the user. FIG. 7A shows a cross-sectional side view of the electrical enclosure system 700. FIG. 7B shows a top view of the electrical enclosure system 700. FIG. 7C shows a cross-sectional back view of the electrical enclosure system 700. The orientation of the mounting handle 505 with respect to the mounting structure 501 for the electrical enclosure system 700 of FIGS. 7A-7C is substantially the same as orientation of the mounting handle 505 with respect to the mounting structure 501 for the electrical enclosure system 600 of FIGS. 6A and 6B.

When the inward force to the mounting handle 505 is removed by the user, the resilient device 560 uses its spring force to separate the bracket 550 from the body 520 of the mounting handle. Since the bracket 500 abuts the mounting structure 501, the resilient device 560 is actually pushing the body 520 of the mounting handle 505 away from the mounting structure 501. As the body 520 of the mounting handle 505 is forced away from the mounting structure 501 by the resilient device 560, the interior attachment feature 532, coupled to the body 520 by the stem 531, moves within the cavity 546 toward the opening 548 of the mounting structure 501.

Further, since the orientation of the interior attachment feature 532 in the electrical enclosure system 700 relative to the orientation of the interior attachment feature 532 in the electrical enclosure system 500, the interior attachment feature 532 (and more specifically the top and bottom along the height of the interior attachment feature 532) abuts against the upper lip 545 and the lower lip 544 within the cavity 546. A combination of the interior attachment feature 532 abutting against the upper lip 545 and the lower lip 544 within the cavity 546 of the mounting structure 501 and the resilient device 560 keeping the bracket 550 abutted against the mounting structure 501 cause the mounting handle 505 to remain firmly in place with respect to the mounting structure 501, even when the mounting handle 505 (or the electrical enclosure coupled to the mounting handle 505) is bumped or pushed.

To remove the mounting handle 505 from the mounting structure 501, the process is reversed. In other words, an inward force is again applied to the mounting handle 505, which stops the interior attachment feature 532 from abutting against the upper lip 545 and the lower lip 544 and moves the interior attachment feature 532 further into the cavity 546 toward the back wall 543 of the mounting structure 501. When this is done, the user can rotate the mounting handle 505 (including the interior attachment feature 532) to change its orientation with respect to the mounting structure 501. When the profile of the interior attachment feature 532 can pass through the opening 548, the user can apply an outward force to the mounting handle 505, physically separating the mounting handle 505 from the mounting structure 501.

Example embodiments provide for mounting handles for electrical enclosures. Specifically, certain example embodiments allow for handles coupled to electrical enclosures, where the handles have one or more features that allow the handle to become detachably coupled to a mounting structure by a user. Example mounting handles for electrical enclosures allow an electrical enclosure to be moved and temporarily secured. This can be useful when a user has to perform maintenance, install new equipment, replace existing equipment, or rearrange equipment. Example embodiments allow electrical enclosures can be lifted, temporarily secured, and/or otherwise maneuvered by a user with significantly reduced risk of mechanical damage to the electrical enclosure and equipment associated with the electrical enclosure, and with reduced risk of disrupting the electrical continuity within the electrical enclosure. The example mounting handles of electrical enclosures described herein can be coupled to and decoupled from a mounting structure without the use of (or with limited use of) tools. Example embodiments may be used with a variety of sizes, quantities, shapes, and/or configurations of electrical enclosure and/or mounting structure.

Although embodiments described herein are made with reference to example embodiments, it should be appreciated by those skilled in the art that various modifications are well within the scope and spirit of this disclosure. Those skilled in the art will appreciate that the example embodiments described herein are not limited to any specifically discussed application and that the embodiments described herein are illustrative and not restrictive. From the description of the example embodiments, equivalents of the elements shown therein will suggest themselves to those skilled in the art, and ways of constructing other embodiments using the present disclosure will suggest themselves to practitioners of the art. Therefore, the scope of the example embodiments is not limited herein.

What is claimed is:

1. A handle for mounting an electrical enclosure to a mounting structure, the handle comprising:
a base comprising at least one enclosure coupling feature, wherein the at least one enclosure coupling feature is configured to couple to the electrical enclosure;
a body disposed adjacent to the base; and
a structure coupling feature that protrudes from the body, wherein the structure coupling feature is configured to removably couple to the mounting structure,
wherein the mounting structure comprises an opening in which the structure coupling feature is disposed.

2. The handle of claim 1, wherein the structure coupling feature comprises:
a stem coupled to the body; and
an interior attachment feature disposed at a distal end of the stem, wherein the interior attachment feature has a length and a width, wherein the length is longer than a height of an opening in the mounting structure, and wherein the width is shorter than the height of the opening in the mounting structure.

3. The handle of claim 2, wherein mounting structure has a C-shaped profile that forms the opening, wherein the interior attachment feature is inserted through the opening in the C-shaped profile of the mounting structure in a first orientation, wherein the interior attachment feature is rotated to a second orientation after the interior attachment feature is inserted through the opening in the C-shaped profile of the mounting structure, wherein the first orientation and the second orientation are approximately perpendicular to each other.

4. The handle of claim 2, wherein the length of the interior attachment feature is aligned with a length of the body.

5. The handle of claim 2, wherein the interior attachment feature comprises two rounded corners disposed at diagonally opposite ends of the interior attachment feature.

6. The handle of claim 5, wherein the stem comprises two rounded corners disposed at diagonally opposite ends of the stem along a thickness of the stem.

7. The handle of claim 2, wherein the stem has a length that is at least as long as a depth of the opening in the C-shaped profile of the mounting structure.

8. The handle of claim 2, wherein the structure coupling feature further comprises:
a bracket movably disposed around the stem between the body of the handle and the interior attachment feature.

9. The handle of claim 8, wherein bracket has a length that is greater than height of the C-shaped profile of the mounting structure.

10. The handle of claim 9, wherein the bracket comprises a pair of extensions disposed at opposite ends of the length of the bracket, wherein the pair of extensions extend substantially perpendicular from a remainder of the bracket toward the interior attachment feature.

11. The handle of claim 8, wherein the structure coupling feature further comprises:
a first resilient device disposed around the stem and disposed between the bracket and the body, wherein the first resilient device has a first spring force.

12. The handle of claim 11, wherein the first spring force of the first resilient device secures the bracket against the C-shaped profile of the mounting structure.

13. The handle of claim 12, wherein the structure coupling feature further comprises:
a second resilient device disposed around the stem and disposed between the bracket and the interior attachment feature, wherein the second resilient device has a second spring force.

14. The handle of claim 13, wherein the first spring force is greater than the second spring force.

15. The handle of claim 2, wherein the structure coupling feature further comprises:
a pin that protrudes from a distal face of the interior attachment feature, wherein the pin is configured to be disposed within an aperture that traverses a back wall of the C-shaped profile of the mounting structure.

16. The handle of claim 15, wherein the pin is retractable.

17. The handle of claim 15, wherein the structure coupling feature further comprising:
a resilient device disposed around the pin.

18. An electrical enclosure comprising:
a housing; and
a handle coupled to and disposed on an exterior surface of the housing, wherein the handle comprises:
a base comprising at least one enclosure coupling feature, wherein the at least one enclosure coupling feature is configured to couple to the housing;
a body disposed adjacent to the base; and
a structure coupling feature that protrudes from the body, wherein the structure coupling feature is configured to removably couple to the mounting structure,
wherein the mounting structure comprises an opening in which the structure coupling feature is disposed.

19. An electrical enclosure system comprising:
a mounting structure comprising an opening;
an electrical enclosure; and
a handle coupled to and disposed on an exterior surface of the electrical enclosure, wherein the handle comprises:
a base comprising at least one enclosure structure coupling feature, wherein the at least one enclosure structure coupling feature is coupled to the electrical enclosure;
a body disposed adjacent to the base; and
a coupling feature that protrudes from the body, wherein the structure coupling feature is removably disposed in the opening and coupled to the mounting structure.

20. The electrical enclosure system of claim 19, wherein the handle is coupled to and uncoupled from the mounting structure without tools.
